(19) United States
(12) Patent Application Publication
(10) Pub. No.: US 2023/0323533 A1
(43) Pub. Date: Oct. 12, 2023

(54) SUBSTRATE PROCESSING METHOD

(71) Applicant: JUSUNG ENGINEERING CO., LTD., Gwangju-si, Gyeonggi-do (KR)

(72) Inventors: Se Whan JIN, Gwangju-si, Gyeonggi-do (KR); Jae Sung ROH, Gwangju-si, Gyeonggi-do (KR); Cheong SON, Gwangju-si, Gyeonggi-do (KR); Hong Min YOON, Gwangju-si, Gyeonggi-do (KR); Hong Soo YOON, Gwangju-si, Gyeonggi-do (KR); Youn Joo JANG, Gwangju-si, Gyeonggi-do (KR); Byoung Ha CHO, Gwangju-si, Gyeonggi-do (KR); Ji Hyun CHO, Gwangju-si, Gyeonggi-do (KR)

(21) Appl. No.: 18/021,554

(22) PCT Filed: Sep. 24, 2021
(86) PCT No.: PCT/KR2021/012999

§ 371 Date: Feb. 15, 2023

(30) Foreign Application Priority Data
Sep. 29, 2020 (KR) 10-2020-0126824
Sep. 17, 2021 (KR) 10-2021-0125030

(51) Int. Cl. C23C 16/44; C23C 16/455; C23C 16/458

(52) U.S. Cl. CPC C23C 16/45523; C23C 16/4408; C23C 16/4584

(57) ABSTRACT

The present inventive concept relates to a substrate processing method in which a processing process is performed on a substrate in a processing space divided into a first processing region and a second processing region. The substrate processing method comprises the steps of: performing a first processing process on a substrate in the first processing region when the substrate supported by the support part is positioned in the first processing region; moving the substrate to the second processing region by rotating the support part when the first processing process is completed; and performing a second processing process on the substrate in the second processing region when the substrate supported by the support part is positioned in the second processing region.

### TECHNICAL FIELD

The present disclosure relates to a method for processing a substrate, which performs a processing process such as a deposition process and an etching process on a substrate.

### BACKGROUND ART

Generally, a thin-film layer, a thin-film circuit pattern, or an optical pattern should be formed on a substrate for manufacturing a solar cell, a semiconductor device, a flat panel display device, etc. To this end, a processing process is performed on a substrate, and examples of the processing process include a deposition process of depositing a thin film including a specific material on the substrate, a photo process of selectively exposing a portion of a thin film by using a photosensitive material, an etching process of removing the selectively exposed portion of the thin film to form a pattern, etc.

Such a processing process on a substrate is performed by a substrate processing apparatus. The substrate processing apparatus includes a chamber which provides a processing space, a supporting unit which supports a substrate, and a gas injection unit which injects a gas toward the supporting unit. The substrate processing apparatus performs a processing process on a substrate by using a source gas and a reactant gas injected by the gas injection unit.

Recently, the demand for a device having various characteristics like a doping device and a device having a multi thin film structure is increasing, but the related art has been implemented to perform a processing process under a condition where the gas injection unit always injects a constant gas and the supporting unit rotates continuously at a certain rotation speed without stop. Therefore, the related art has a problem where it is difficult to perform a processing process for manufacturing a device having various characteristics like a doping device and a device having a multi thin film structure.

### DISCLOSURE

### Technical Problem

The present inventive concept is devised to solve the above-described problem and is for providing a substrate processing method which may perform a processing process for manufacturing a device having various characteristics like a doping device and a device having a multi thin film structure.

### Technical Solution

To accomplish the above-described objects, the present inventive concept may include the following elements.

A substrate processing method according to the present inventive concept is a method for processing a substrate, which performs a processing process on a substrate in a processing space divided into a first processing region and a second processing region, and may include: a step of performing a first processing process on a substrate in the first processing region when the substrate supported by a supporting unit is disposed in the first processing region; a step of rotating the supporting unit to move the substrate to the second processing region, when the first processing process is completed; and a step of performing a second processing process on the substrate in the second processing region when the substrate supported by the supporting unit is disposed in the second processing region.

In the substrate processing method according to the present inventive concept, the step of performing the first processing process may include: a step of injecting a first source gas into the first processing region; and a step of injecting a second source gas into the first processing region.

In the substrate processing method according to the present inventive concept, the step of performing the second processing process may include: a step of injecting a first reactant gas into the second processing region; and a step of injecting a second reactant gas into the second processing region.

In the substrate processing method according to the present inventive concept, the step of performing the second processing process may include: a step of injecting a first reactant gas into the second processing region; and a step of generating plasma in the second processing region.

In the substrate processing method according to the present inventive concept, the step of performing the first processing process may inject a mixed gas, where two or more kinds of source gases are mixed, into the first processing region. The step of performing the second processing process may inject a mixed gas, where two or more kinds of reactant gases are mixed, into the second processing region.

A substrate processing method according to the present inventive concept is a method for processing a substrate, which performs a processing process on a substrate in a processing space divided into a first processing region and a second processing region, and may include: a step of injecting a first source gas into the first processing region to perform a first processing process using the first source gas, when the substrate supported by a supporting unit is disposed in the first processing region; a step of rotating the supporting unit to move the substrate to the second processing region, when the first processing process using the first source gas is completed; a step of injecting a first reactant gas into the second processing region to perform a second processing process using the first reactant gas, when the substrate on which the first processing process using the first source gas has been performed is disposed in the second processing region; a step of rotating the supporting unit to move the substrate to the first processing region, when the second processing process using the first reactant gas is completed; a step of injecting a second source gas, differing from the first source gas, into the first processing region to perform a first processing process using the second source gas, when the substrate on which the second processing process using the first reactant gas has been performed is disposed in the first processing region; a step of rotating the supporting unit to move the substrate to the second processing region, when the first processing process using the second source gas is completed; and a step of injecting a second reactant gas, differing from the first reactant gas, into the second processing region to perform a second processing process using the second reactant gas, when the substrate on which the first processing process using the second source gas has been performed is disposed in the second processing region.

### Advantageous Effect

According to the present inventive concept, the following effects may be realized.

The present inventive concept may be implemented to adjust a time for which each of a processing process using a source gas and a processing process using a reactant gas is performed, and thus, an incubation time needed for thin film growth may be adjusted in each of the processing process using the source gas and the processing process using the reactant gas. Accordingly, the present inventive concept may perform a processing process for manufacturing a device having various characteristics like a doping device and a device having a multi thin film structure.

The present inventive concept may be implemented to spatially divide a processing region where each of a processing process using a source gas and a processing process using a reactant gas is performed. Accordingly, the present inventive concept may increase a cleaning period of an inner portion of a chamber, and thus, may reduce the cleaning cost and may also increase an operating rate, thereby increasing the productivity of a substrate on which a processing process is completed.

### DESCRIPTION OF DRAWINGS

FIG. 1 is a schematic exploded perspective view illustrating an example of a substrate processing apparatus for performing a substrate processing method according to the present inventive concept.

FIG. 2 is a schematic side cross-sectional view of a substrate processing apparatus taken along line I-I of FIG. 1.

FIG. 3 is a schematic plan view of a supporting unit in the substrate processing apparatus of FIG. 1.

FIG. 4 is a schematic flowchart of a substrate processing method according to the present inventive concept.

FIG. 5 is a schematic flowchart of a first processing process in a substrate processing method according to the present inventive concept.

FIG. 6 is a timing diagram showing an injection interval of a gas in embodiments of a first processing process in a substrate processing method according to the present inventive concept.

FIG. 7 is a schematic flowchart of a second processing process in a substrate processing method according to the present inventive concept.

FIG. 8 is a timing diagram showing an injection period of a gas in embodiments of a second processing process in a substrate processing method according to the present inventive concept.

FIG. 9 is a timing diagram showing a movement interval of a substrate and an injection interval of a gas in a substrate processing method according to a modified embodiment of the present inventive concept.

### MODE FOR INVENTION

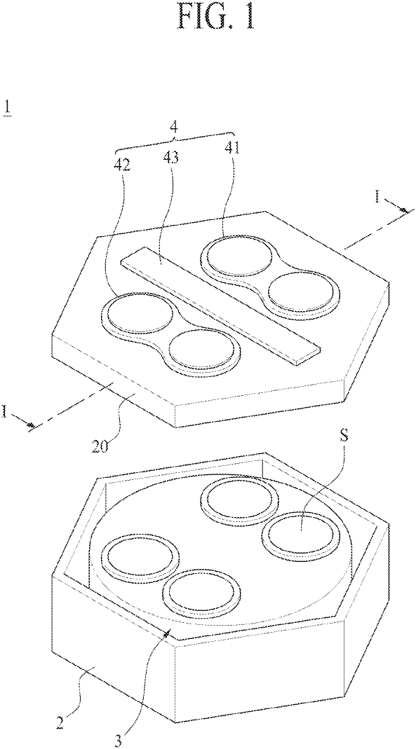

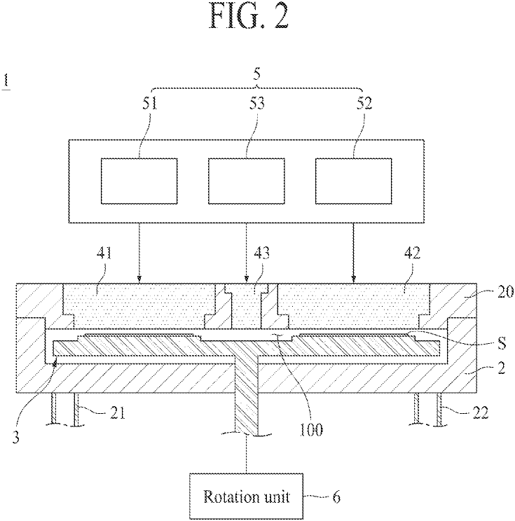

Referring to FIGS. 1 and 2, a substrate processing method according to the present inventive concept performs a processing process on a substrate S. The substrate S may be a silicon substrate, a glass substrate, a metal substrate, or the like. The substrate processing method according to the present inventive concept may perform a deposition process of depositing a thin film on the substrate S, an etching process of removing a portion of the thin film deposited on the substrate, etc. Hereinafter, an embodiment where the substrate processing method according to the present inventive concept performs the deposition process will be described mainly, and based thereon, it is obvious to those skilled in the art that an embodiment is devised where the substrate processing method according to the present inventive concept performs another processing process such as the etching process.

The substrate processing method according to the present inventive concept may be performed by a substrate processing apparatus 1. Before describing an embodiment of the substrate processing method according to the present inventive concept, the substrate processing apparatus 1 will be described below in detail.

Referring to FIGS. 1 to 3, the substrate processing apparatus 1 may include a chamber 2, a supporting unit 3, a gas injection unit 4, and a gas supply unit 5.

Referring to FIGS. 1 to 3, the chamber 2 provides a processing space 100. A processing process such as a deposition process and an etching process on the substrate S may be performed in the processing space 100. The processing space 100 may be divided into a first processing region 110 and a second processing region 120 in the chamber 2. A third processing region 130 may be disposed between the first processing region 110 and the second processing region 120. The supporting unit 3 and the gas injection unit 4 may be installed in the chamber 2. A first exhaust port 21 and a second exhaust port 22 may be coupled to the chamber 2. The first exhaust port 21 may be connected to the first processing region 110. Therefore, a gas disposed in the first processing region 110 may be exhausted to the outside of the chamber 2 through the first exhaust port 21. The second exhaust port 22 may be connected to the second processing region 120. Accordingly, a gas disposed in the second processing region 120 may be exhausted to the outside of the chamber 2 through the second exhaust port 22.

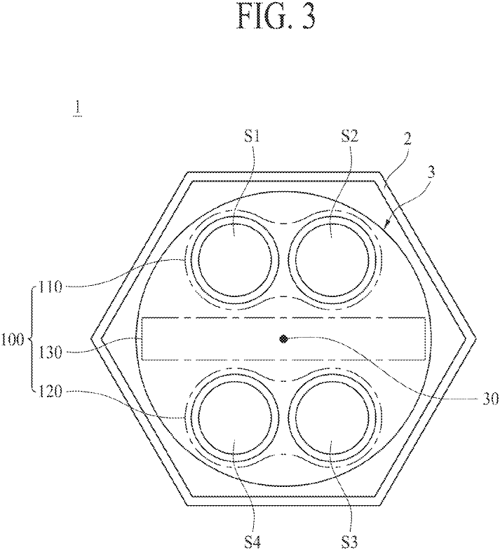

Referring to FIGS. 1 to 3, the supporting unit 3 may be installed in the chamber 2. The supporting unit 3 may support one substrate S, or may support a plurality of substrates S1 to S4 (illustrated in FIG. 3). When the processing space 100 includes the first processing region 110, the second processing region 120, and the third processing region 130, a portion of the supporting unit 3 may be disposed in the first processing region 110, and another portion of the supporting unit 3 may be disposed in the third processing region 130. In a case where the plurality of substrates S1 to S4 are supported by the supporting unit 3, some of the plurality of substrates S1 to S4 may be disposed in the first processing region 110, and the other thereof may be supported by the supporting unit 3 so as to be disposed in the second processing region 120.

The supporting unit 3 may rotate about a supporting shaft 30 (illustrated in FIG. 3) of the supporting unit 3 in the chamber 2. The substrate S supported by the supporting unit 3 may move to each of the other processing regions in the chamber 2 through a rotation of the supporting unit 3. When the supporting unit 3 rotates, some of the plurality of substrates S1 to S4 may move to the second processing region 120 via the third processing region 130 from the first processing region 110 and may again move to the first processing region 110 via the third processing region 130 from the second processing region 120. A rotation of the supporting unit 3 may be performed through repeated stop and rotation. Therefore, the substrate S supported by the supporting unit 3 may move between different processing regions through repeated stop and movement. The supporting unit 3 may be rotated about the supporting shaft 30 by a rotation unit 6. The rotation and stop of the supporting unit 3 may be repeatedly performed by the rotation unit 6.

Referring to FIGS. 1 to 3, the gas injection unit 4 injects a gas toward the supporting unit 3. The gas injection unit 4 may be connected to the gas supply unit 5. Therefore, the gas injection unit 4 may inject a gas, supplied from the gas supply unit 5, toward the supporting unit 3. The gas injection unit 4 may be disposed to be opposite to the supporting unit 3. The processing space 100 may be disposed between the gas injection unit 4 and the supporting unit 3. The gas injection unit 4 may be coupled to a chamber lid 20. The chamber lid 20 may be coupled to the chamber 2 to cover an upper portion of the chamber 2.

The gas injection unit 4 may include a first injection unit 41 and a second injection unit 42.

The first injection unit 41 injects a gas into the first processing region 110. The first processing region 110 may correspond to a portion of the processing space 100. The first injection unit 41 may be disposed upward apart from the supporting unit 3. In this case, the first processing region 110 may be a region between the first injection unit 41 and the supporting unit 3. The first injection unit 41 may inject at least one kind of source gas into the first processing region 110. The first injection unit 41 may inject a purge gas into the first processing region 110. The purge gas may be an inert gas such as argon (Ar).

The second injection unit 42 injects a gas into the second processing region 120. The second processing region 120 may correspond to a portion of the processing space 100. The second injection unit 42 may be disposed upward apart from the supporting unit 3. In this case, the second processing region 120 may be a region between the second injection unit 42 and the supporting unit 3. The second injection unit 42 may inject at least one kind of reactant gas into the second processing region 120. The second injection unit 42 may inject a purge gas into the second processing region 120.

The gas injection unit 4 may further include a third injection unit 43.

The third injection unit 43 injects a gas into the third processing region 130. The third processing region 130 may correspond to a portion of the processing space 100. The third processing region 130 may be a region between the first processing region 110 and the second processing region 120. The third injection unit 43 may be disposed upward apart from the supporting unit 3. The third injection unit 43 may be disposed between the first injection unit 41 and the second injection unit 42. The third injection unit 43 may inject a division gas into the third processing region 130. The division gas may be an inert gas such as argon (Ar). As the third injection unit 43 injects the division gas into the third processing region 130, the first processing region 110 and the second processing region 120 may be spatially separated from each other so that a gas is not mixed therebetween.

Referring FIGS. 1 to 3, the gas supply unit 5 supplies a gas to the gas injection unit 4. The gas supply unit 5 may supply a gas to each of the first injection unit 41 and the second injection unit 42. The gas supply unit 5 may supply a gas to the third injection unit 43. The gas supply unit 5 may be installed inside the chamber 2 or outside the chamber 2.

The gas supply unit 5 may include a first supply unit 51 and a second supply unit 52.

The first supply unit 51 may supply at least one kind of source gas to the first injection unit 41. The first supply unit 51 may supply a purge gas to the first injection unit 41. In this case, the first supply unit 51 may supply at least one kind of source gas and a purge gas to the first injection unit 41 in a predetermined process sequence.

The second supply unit 52 may supply at least one kind of reactant gas to the second injection unit 42. The second supply unit 52 may supply a purge gas to the second injection unit 42. In this case, the second supply unit 52 may supply at least one kind of reactant gas and a purge gas to the second injection unit 42 in a predetermined process sequence.

The gas supply unit 5 may further include a third supply unit 53.

The third supply unit 53 may supply a division gas to the third injection unit 43. The third supply unit 53 may intermittently or continuously supply a division gas to the third injection unit 43 while a processing process is being performed on the substrate S.

The substrate processing method according to the present inventive concept may be performed by using the substrate processing apparatus 1, but is not limited thereto and may be performed by using a substrate processing apparatus which is differently implemented.

Hereinafter, an embodiment of a substrate processing method according to the present inventive concept will be described in detail with reference to the accompanying drawings.

Referring to FIGS. 1 to 4, the substrate processing method according to the present inventive concept may include the following steps.

First, a first processing process is performed in the first processing region (S10). A step (S10) of performing the first processing process may be performed in a state where the substrate S supported by the supporting unit 3 is disposed in the first processing region 110 and a rotation of the supporting unit 3 stops. When the substrate S supported by the supporting unit 3 is disposed in the first processing region 110, the step (S10) of performing the first processing process may be performed by the first injection unit 41 injecting a gas into the first processing region 110. In this case, the first injection unit 41 may inject at least one kind of source gas into the first processing region 110. As the source gas is injected into the first processing region 110, an adsorption process of adsorbing a source material onto the substrate S may be performed in the first processing region 110. The first injection unit 41 may inject the source gas into the first processing region 110, and then, may inject a purge gas into the first processing region 110.

Subsequently, the substrate may move from the first processing region to the second processing region (S20). A step (S20) of moving the substrate from the first processing region to the second processing region may be performed after the first processing process is completed through the step (S10) of performing the first processing process. When the first processing process is completed, the step (S20) of moving the substrate from the first processing region to the second processing region may be performed by the rotation unit 6 rotating the supporting unit 3 with respect to the supporting shaft 30. When the substrate S disposed in the first processing region 110 is disposed in the second processing region 120, the rotation unit 6 may stop a rotation of the supporting unit 3. The step (S20) of moving the substrate from the first processing region to the second processing region may be performed by rotating the supporting unit 3 so that the substrate S disposed in the first processing region 110 moves to the second processing region 120 via the third processing region 130. When the substrate S is passing through the third processing region 130, a purge gas may be injected onto the substrate S by the third injection unit 43.

Subsequently, a second processing process is performed in the second processing region (S30). A step (S30) of performing the second processing process may be performed in a state where the substrate S supported by the supporting unit 3 is disposed in the second processing region 120 and a rotation of the supporting unit 3 stops. When the substrate S supported by the supporting unit 3 is disposed in the second processing region 120, the step (S30) of performing the second processing process may be performed by the second injection unit 42 injecting a gas into the second processing region 120. In this case, the second injection unit 42 may inject at least one kind of reactant gas into the second processing region 120. As the reactant gas is injected into the second processing region 120, a deposition process of depositing a thin film though a reaction between the reactant gas and a source material adsorbed onto the substrate S may be performed in the second processing region 120. The second injection unit 42 may inject the reactant gas into the second processing region 120, and then, may inject a purge gas into the second processing region 120.

Subsequently, the substrate may move from the second processing region to the first processing region (S40). A step (S40) of moving the substrate from the second processing region to the first processing region may be performed after the second processing process is completed through the step (S30) of performing the second processing process. When the second processing process is completed, the step (S40) of moving the substrate from the second processing region to the first processing region may be performed by the rotation unit 6 rotating the supporting unit 3 with respect to the supporting shaft 30. When the substrate S disposed in the second processing region 120 is disposed in the first processing region 110, the rotation unit 6 may stop a rotation of the supporting unit 3. The step (S40) of moving the substrate from the second processing region to the first processing region may be performed by rotating the supporting unit 3 so that the substrate S disposed in the second processing region 120 moves to the first processing region 110 via the third processing region 130. When the substrate S is passing through the third processing region 130, a purge gas may be injected onto the substrate S by the third injection unit 43.

As described above, the substrate processing method according to the present inventive concept is implemented to perform the first processing process and the second processing process in a state where a substrate supported by the supporting unit 3 stops. Therefore, the substrate processing method according to the present inventive concept may adjust a time for which each of the first processing process and the second processing process is performed, and thus, may adjust an incubation time needed for thin film growth in each of the first processing process and the second processing process. Therefore, the substrate processing method according to the present inventive concept may perform a processing process for manufacturing a device having various characteristics like a doping device and a device having a multi thin film structure. Also, in the substrate processing method according to the present inventive concept, the first processing region 110 where the first processing process is performed and the second processing region 120 where the second processing process is performed may be spatially separated from each other by a division gas, and thus, an inner portion of the chamber 2 may be prevented from being contaminated by a reaction between a source gas and a reactant gas. Accordingly, the substrate processing method according to the present inventive concept may increase a cleaning period of the inner portion of the chamber 2, and thus, may reduce the cleaning cost and may also increase an operating rate, thereby increasing the productivity of a substrate on which a processing process is completed.

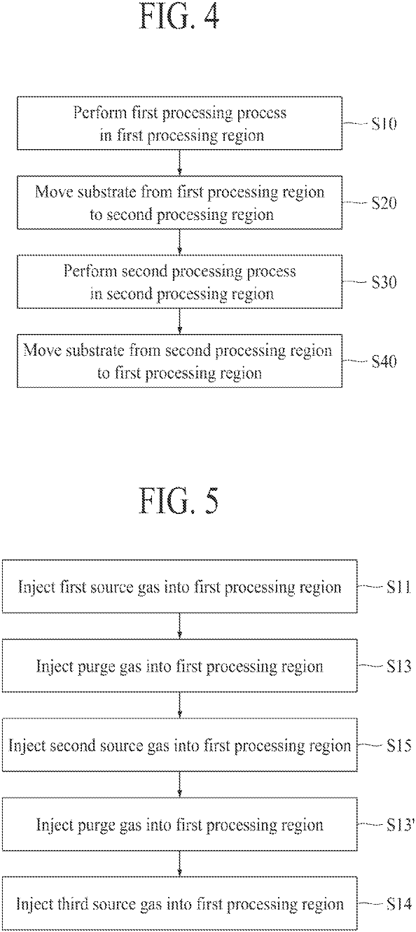

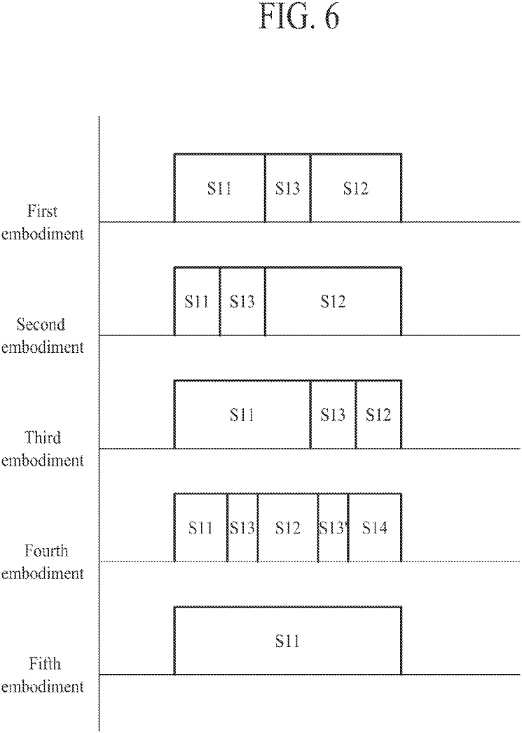

Here, the substrate processing method according to the present inventive concept may include embodiments of the step (S10) of performing the first processing process. Embodiments of the step (S10) of performing the first processing process will be described in detail with reference to FIGS. 1 to 6. In FIG. 6, the abscissa axis denotes a time.

A first embodiment of the step (S10) of performing the first processing process may include a step (S11) of injecting a first source gas and a step (S12) of injecting a second source gas.

The step (S11) of injecting the first source gas may be performed by injecting the first source gas into the first processing region 110. The step (S11) of injecting the first source gas may be performed by the first injection unit 41. The step (S11) of injecting the first source gas may be performed in a state where a rotation of the supporting unit 3 stops.

The step (S12) of injecting the second source gas may be performed by injecting the second source gas into the first processing region 110. The step (S12) of injecting the second source gas may be performed after the step (S11) of injecting the first source gas is performed. The step (S12) of injecting the second source gas may be performed by the first injection unit 41. The step (S12) of injecting the second source gas may be performed in a state where a rotation of the supporting unit 3 stops.

The step (S12) of injecting the second source gas may be performed by injecting the second source gas which differs from the first source gas. In this case, an adsorption process using different kinds of source gases may be sequentially performed on the substrate S, and a composite film based on doping may be formed. Therefore, the substrate processing method according to the present inventive concept may be implemented to perform a processing process for manufacturing a device having various characteristics like a doping device. As described above, a first embodiment of the step (S10) of performing the first processing process may be implemented to inject different source gases, and thus, a multi metal component may be included in a film. For example, the first embodiment of the step (S10) of performing the first processing process may form a metal film including one or more metals of hafnium (Hf), zirconium (Zr), yttrium (Y), and magnesium (Mg).

The step (S12) of injecting the second source gas may be performed by injecting the same second source gas as the first source gas. In this case, an adsorption process using the same kind of source gas may be repeatedly performed on the substrate S, and a thin film having a dense structure may be formed.

The step (S10) of performing the first processing process may include a step (S13) of injecting a purge gas. The step (S13) of injecting the purge gas may be performed by injecting the purge gas into the first processing region 110. The step (S13) of injecting the purge gas may be performed by the first injection unit 41. The step (S13) of injecting the purge gas may be performed in a state where a rotation of the supporting unit 3 stops.

The step (S13) of injecting the purge gas may be performed after the step (S11) of injecting the first source gas is performed and before the step (S12) of injecting the second source gas is performed. That is, the step (S13) of injecting the purge gas may be performed between the step (S11) of injecting the first source gas and the step (S12) of injecting the second source gas. Therefore, the substrate processing method according to the present inventive concept may inject the second source gas after purging the first source gas, which is not adsorbed onto the substrate S, by using the purge gas, thereby enhancing the quality of a substrate on which the first processing process is completed. In this case, the first embodiment of the step (S10) of performing the first processing process may be implemented so that the first source gas and the second source gas include the same source gas, and thus, the same source gas is continuously injected in the same space. Because a source gas act as a seed for depositing a lower seed film, the first embodiment of the step (S10) of performing the first processing process may be implemented so that the adsorption of a source material through the injection of the source gas and purge based on the injection of a purge gas are continuously performed, and thus, the adsorption of the source material may be performed well, thereby increasing a density of a metal seed.

In the first embodiment of the step (S10) of performing the first processing process, the step (S11) of injecting the first source gas may be performed by injecting the first source gas for a first source injection time. The step (S12) of injecting the second source gas may be performed by injecting the second source gas for a second source injection time. In this case, the first source injection time and the second source injection time may be implemented identically. Accordingly, the substrate processing method according to the present inventive concept may be implemented so that an adsorption process using the first source gas and an adsorption process using the second source gas are performed for the same time.

Comparing with the first embodiment of the step (S10) of performing the first processing process described above, a second embodiment of the step (S10) of performing the first processing process has a difference in that the first source injection time and the second source injection time are differently implemented. The second embodiment of the step (S10) of performing the first processing process may be implemented so that the first source injection time is shorter than the second source injection time. Accordingly, the substrate processing method according to the present inventive concept may be implemented so that the adsorption process using the first source gas is performed for a shorter time than the adsorption process using the second source gas.

Comparing with the first embodiment of the step (S10) of performing the first processing process described above, a third embodiment of the step (S10) of performing the first processing process has a difference in that the first source injection time and the second source injection time are differently implemented. The third embodiment of the step (S10) of performing the first processing process may be implemented so that the first source injection time is longer than the second source injection time. Accordingly, the substrate processing method according to the present inventive concept may be implemented so that the adsorption process using the first source gas is performed for a longer time than the adsorption process using the second source gas.

In the second embodiment and the third embodiment of the step (S10) of performing the first processing process, the first source gas and the second source gas may include the same source gas. Therefore, the second embodiment and the third embodiment of the step (S10) of performing the first processing process may be implemented to continuously inject the same source gas in the same space. Therefore, the second embodiment and the third embodiment of the step (S10) of performing the first processing process may be implemented so that the adsorption of a source material through the injection of a source gas and purge based the injection of a purge gas are continuously performed, and thus, the adsorption of the source material may be performed well, thereby increasing a density of a metal seed.

In the second embodiment and the third embodiment of the step (S10) of performing the first processing process, the first source gas and the second source gas may include different source gases. Therefore, in the second embodiment and the third embodiment of the step (S10) of performing the first processing process, a multi metal component may be included in a film. For example, the second embodiment and the third embodiment of the step (S10) of performing the first processing process may form a metal film including one or more metals of hafnium (Hf), zirconium (Zr), yttrium (Y), and magnesium (Mg).

Moreover, the second embodiment and the third embodiment of the step (S10) of performing the first processing process may be implemented to inject the first source gas and the second source gas including different source gases for the first source injection time and the second source injection time which differ. Accordingly, the second embodiment and the third embodiment of the step (S10) of performing the first processing process may increase a ratio of in-film desired metal and may enhance the accuracy of adjustment of a ratio of metal included in a film.

Comparing with the first to third embodiments of the step (S10) of performing the first processing process, a fourth embodiment of the step (S10) of performing the first processing process may further include a step (S14) of injecting a third source gas.

The step (S14) of injecting the third source gas may be performed by injecting the third source gas into the first processing region 110. The step (S14) of injecting the third source gas may be performed after the step (S12) of injecting the second source gas is performed. The step (S14) of injecting the third source gas may be performed by the first injection unit 41. The step (S14) of injecting the third source gas may be performed in a state where a rotation of the supporting unit 3 stops.

The step (S14) of injecting the third source gas may be performed by injecting the third source gas which differs from the first source gas and the second source gas. In this case, an adsorption process using different kinds of source gases may be sequentially performed on the substrate S, and a composite film based on doping may be formed. Therefore, the substrate processing method according to the present inventive concept may be implemented to perform a processing process for manufacturing a device having more various characteristics.

The step (S14) of injecting the third source gas may be performed by injecting the third source gas which is the same as at least one of the first source gas and the second source gas. In this case, an adsorption process using the same kind of source gas may be repeatedly performed on the substrate S, and a thin film having a dense structure may be formed.

In the fourth embodiment of the step (S10) of performing the first processing process, a step (S13′) of injecting the purge gas may be performed between the step (S12) of injecting the second source gas and the step (S14) of injecting the third source gas.

The fourth embodiment of the step (S10) of performing the first processing process may be implemented so that the first source gas, the second source gas, and the third source gas include the same source gas, and thus, the same source gas is continuously injected in the same space. Therefore, the fourth embodiment of the step (S10) of performing the first processing process may be implemented so that the adsorption of a source material through the injection of a source gas and purge based the injection of a purge gas are continuously performed, and thus, the adsorption of the source material may be performed well, thereby increasing a density of a metal seed.

In the fourth embodiment of the step (S10) of performing the first processing process, the first source gas, the second source gas, and the third source gas may include different source gases. Therefore, in the fourth embodiment of the step (S10) of performing the first processing process, a multi metal component may be included in a film. For example, the fourth embodiment of the step (S10) of performing the first processing process may form a metal film including one or more metals of hafnium (Hf), zirconium (Zr), yttrium (Y), and magnesium (Mg).

Although not shown, the step (S10) of performing the first processing process may be implemented as an embodiment which includes four or more steps of injecting a source gas. In this case, the step (S13) of injecting the purge gas may be performed between steps of injecting a source gas.

A fifth embodiment of the step (S10) of performing the first processing process may include only the step (S11) of injecting the first source gas. In this case, the step (S11) of injecting the first source gas may be performed by injecting a mixed gas, where two or more kinds of source gases are mixed, as the first source gas into the first processing region 110.

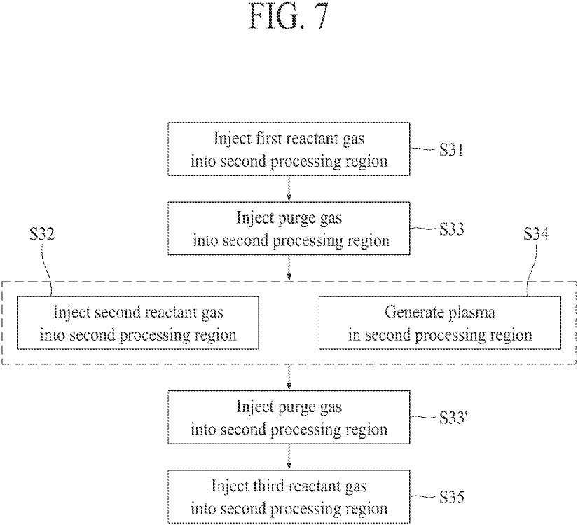

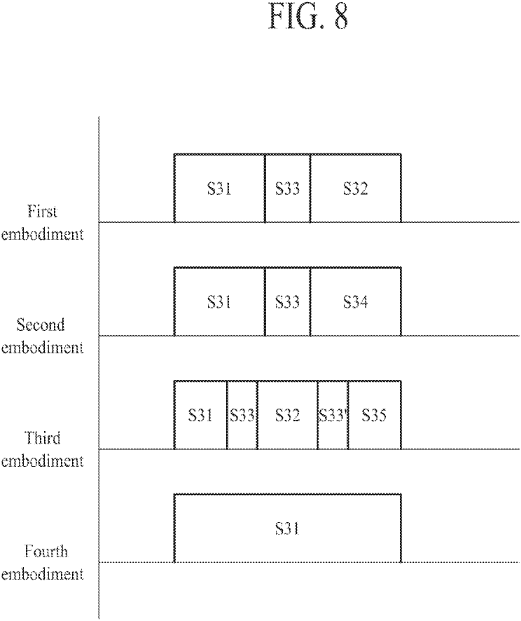

Here, the substrate processing method according to the present inventive concept may include embodiments of the step (S30) of performing the second processing process. Embodiments of the step (S30) of performing the second processing process will be described in detail with reference to FIGS. 1 to 8. In FIG. 8, the abscissa axis denotes a time.

A first embodiment of the step (S30) of performing the second processing process may include a step (S31) of injecting a first reactant gas and a step (S32) of injecting a second reactant gas.

The step (S31) of injecting the first reactant gas may be performed by injecting the first reactant gas into the second processing region 120. The step (S31) of injecting the first reactant gas may be performed by the second injection unit 42. The step (S31) of injecting the first reactant gas may be performed in a state where a rotation of the supporting unit 3 stops.

The step (S32) of injecting the second reactant gas may be performed by injecting the second reactant gas into the second processing region 120. The step (S32) of injecting the second reactant gas may be performed after the step (S31) of injecting the first reactant gas is performed. The step (S32) of injecting the second reactant gas may be performed by the second injection unit 42. The step (S32) of injecting the second reactant gas may be performed in a state where a rotation of the supporting unit 3 stops.

The step (S32) of injecting the second reactant gas may be performed by injecting the second reactant gas which differs from the first reactant gas. In this case, an adsorption process using different kinds of reactant gases may be sequentially performed on the substrate S, and a composite film based on doping may be formed. Therefore, the substrate processing method according to the present inventive concept may be implemented to perform a processing process for manufacturing a device having various characteristics like a doping device.

The step (S32) of injecting the second reactant gas may be performed by injecting the same second reactant gas as the first reactant gas. In this case, an adsorption process using the same kind of reactant gas may be repeatedly performed on the substrate S, and a thin film having a dense structure may be formed.

As described above, the first embodiment of the step (S30) of performing the second processing process may be implemented to inject a reactant through the injection of the first reactant gas and the second reactant gas a plurality of times, thereby enhancing film quality.

The step (S30) of performing the second processing process may include a step (S33) of injecting a purge gas. The step (S33) of injecting the purge gas may be performed by injecting the purge gas into the second processing region 120. The step (S33) of injecting the purge gas may be performed by the second injection unit 42. The step (S33) of injecting the purge gas may be performed in a state where a rotation of the supporting unit 3 stops.

The step (S33) of injecting the purge gas may be performed after the step (S31) of injecting the first reactant gas is performed and before the step (S32) of injecting the second reactant gas is performed. That is, the step (S33) of injecting the purge gas may be performed between the step (S31) of injecting the first reactant gas and the step (S32) of injecting the second reactant gas. Therefore, the substrate processing method according to the present inventive concept may inject the second reactant gas after purging the first reactant gas, which is not deposited on the substrate S, by using the purge gas, thereby enhancing the quality of a substrate on which the second processing process is completed.

In the first embodiment of the step (S30) of performing the second processing process, the step (S31) of injecting the first reactant gas may be performed by injecting the first reactant gas for a first reaction injection time. The step (S32) of injecting the second reactant gas may be performed by injecting the second reactant gas for a second reaction injection time. In this case, the first reaction injection time and the second reaction injection time may be implemented identically. Therefore, the substrate processing method according to the present inventive concept may be implemented so that a deposition using the first reactant gas and a deposition using the second reactant gas are performed for the same time. Although not shown, the first reaction injection time and the second reaction injection time may be implemented differently. In this case, the substrate processing method according to the present inventive concept may be implemented so that the deposition using the first reactant gas and the deposition using the second reactant gas are performed for different times.

Comparing with the first embodiment of the step (S30) of performing the second processing process, a second embodiment of the step (S30) of performing the second processing process has a difference in that a step (S34) of generating plasma is performed instead of the step (S32) of injecting the second reactant gas. The step (S34) of generating the plasma may be performed by generating plasma in the second processing region 120. The step (S34) of generating the plasma may be performed by the second injection unit 42. Although not shown, the second injection unit 42 may generate the plasma in the second processing region 120 by using a plasma electrode and a ground electrode. In this case, the second injection unit 42 may inject a generating gas, which is for generating plasma, into the second processing region 120. The second embodiment of the step (S30) of performing the second processing process may perform the step (S30) of performing the second processing process, and thus, may increase a density of a thin film formed by a deposition process using the first reactant gas and may enhance step coverage. Also, the second embodiment of the step (S30) of performing the second processing process may perform processing using the plasma immediately after a film is formed, and thus, may remove impurities included in a metal film and may also increase a density of a film.

Comparing with the first embodiment of the step (S30) of performing the second processing process, a third embodiment of the step (S30) of performing the second processing process may further include a step (S35) of injecting a third reactant gas.

The step (S35) of injecting the third reactant gas may be performed by injecting the third reactant gas into the second processing region 120. The step (S35) of injecting the third reactant gas may be performed after the step (S32) of injecting the second reactant gas is performed. The step (S35) of injecting the third reactant gas may be performed by the second injection unit 42. The step (S35) of injecting the third reactant gas may be performed in a state where a rotation of the supporting unit 3 stops.

The step (S35) of injecting the third reactant gas may be performed by injecting the third reactant gas which differs from the first reactant gas and the second reactant gas. In this case, an adsorption process using different kinds of reactant gases may be sequentially performed on the substrate S, and a composite film based on doping may be formed. Therefore, the substrate processing method according to the present inventive concept may be implemented to perform a processing process for manufacturing a device having more various characteristics.

The step (S14) of injecting the third reactant gas may be performed by injecting the third reactant gas which is the same as at least one of the first reactant gas and the second reactant gas. In this case, an adsorption process using the same kind of reactant gas may be repeatedly performed on the substrate S, and a thin film having a dense structure may be formed.

As described above, the third embodiment of the step (S30) of performing the second processing process may be implemented to inject a reactant through the injection of the first reactant gas, the second reactant gas, and the third reactant gas a plurality of times, thereby enhancing film quality.

In the third embodiment of the step (S30) of performing the second processing process, a step (S33′) of injecting the purge gas may be performed between the step (S32) of injecting the second reactant gas and the step (S35) of injecting the third reactant gas.

Although not shown, the step (S30) of performing the second processing process may be implemented as an embodiment which includes four or more steps of injecting a reactant gas. In this case, the step (S33) of injecting the purge gas may be performed between steps of injecting a reactant gas.

A fourth embodiment of the step (S30) of performing the second processing process may include only the step (S31) of injecting the first reactant gas. In this case, the step (S31) of injecting the first reactant gas may be performed by injecting a mixed gas, where two or more kinds of reactant gases are mixed, as the first reactant gas into the second processing region 120.

Here, the substrate processing method according to the present inventive concept may be implemented by a combination of one of the first to fifth embodiments of the step (S10) of performing the first processing process and one of the first to fourth embodiments of the step (S30) of performing the second processing process. In the substrate processing method according to the present inventive concept, in a case where one of the first to fifth embodiments of the step (S10) of performing the first processing process is performed, the step (S30) of performing the second processing process may include only the step (S31) of injecting the first reactant gas and may be implemented to inject one kind of reactant gas into the second processing region 120. In the substrate processing method according to the present inventive concept, in a case where one of the first to fourth embodiments of the step (S30) of performing the second processing process is performed, the step (S10) of performing the first processing process may include only the step (S11) of injecting the first source gas and may be implemented to inject one kind of source gas into the first processing region 110.

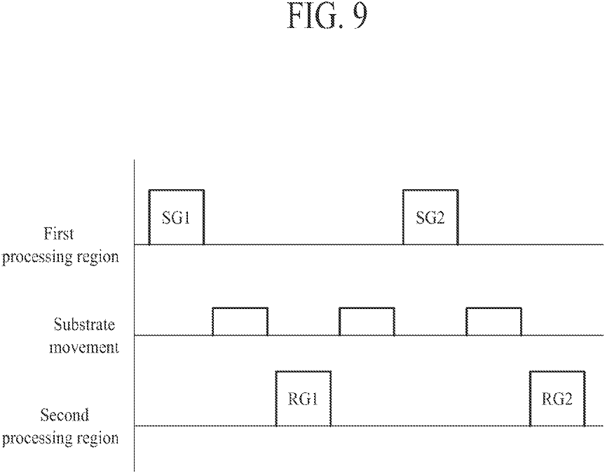

Referring to FIGS. 1 to 3 and 9, a substrate processing method according to a modified embodiment of the present inventive concept may include the following steps. In FIG. 9, the abscissa axis denotes a time.

First, the first processing process using the first source gas is performed. When the substrate S supported by the supporting unit 3 is disposed in the first processing region 110, such a step may be performed by injecting the first source gas into the first processing region 110 to perform the first processing process using the first source gas. The first source gas may be injected into the first processing region 110 by the first injection unit 41. While a step of performing the first processing process using the first source gas is being performed, the supporting unit 3 may be maintained in a stop state.

Subsequently, when the first processing process using the first source gas is completed, the substrate moves to the second processing region 120. When the first processing process using the first source gas is completed, such a step may be performed by moving the substrate S from the first processing region 110 to the second processing region 120. When the substrate S is disposed in the second processing region 120, a rotation of the supporting unit 3 may stop. In a process where the substrate S moves from the first processing region 110 to the second processing region 120, the substrate S may pass through the third processing region 130.

Subsequently, the second processing process using the first reactant gas is performed. When the substrate S supported by the supporting unit 3 is disposed in the second processing region 120, such a step may be performed by injecting the first reactant gas into the second processing region 120 to perform the second processing process using the first reactant gas. The first reactant gas may be injected into the second processing region 120 by the second injection unit 42. While a step of performing the second processing process using the first reactant gas is being performed, the supporting unit 3 may be maintained in a stop state.

Subsequently, when the second processing process using the first reactant gas is completed, the substrate moves to the first processing region 110. When the second processing process using the first reactant gas is completed, such a step may be performed by moving the substrate S from the second processing region 120 to the first processing region 110. When the substrate S is disposed in the first processing region 110, a rotation of the supporting unit 3 may stop. In a process where the substrate S moves from the second processing region 120 to the first processing region 110, the substrate S may pass through the third processing region 130.

Subsequently, the first processing process using the second source gas is performed. When the substrate S supported by the supporting unit 3 is disposed in the first processing region 110, such a step may be performed by injecting the second source gas into the first processing region 110 to perform the first processing process using the second source gas. The second source gas and the first source gas may be different kinds of source gases. The second source gas may be injected into the first processing region 110 by the first injection unit 41. While a step of performing the first processing process using the second source gas is being performed, the supporting unit 3 may be maintained in a stop state.

Subsequently, when the first processing process using the second source gas is completed, the substrate moves to the second processing region 120. When the first processing process using the second source gas is completed, such a step may be performed by rotating the supporting unit 3 to move the substrate S from the first processing region 110 to the second processing region 120.

Subsequently, the second processing process using the second reactant gas is performed. When the substrate S supported by the supporting unit 3 is disposed in the second processing region 120, such a step may be performed by injecting the second reactant gas into the second processing region 120 to perform the second processing process using the second reactant gas. The second reactant gas and the first reactant gas may be different kinds of reactant gases. The second reactant gas may be injected into the second processing region 120 by the second injection unit 42. While a step of performing the second processing process using the second reactant gas is being performed, the supporting unit 3 may be maintained in a stop state.

As described above, the substrate processing method according to a modified embodiment of the present inventive concept is implemented to sequentially perform the first processing process using the first source gas, the second processing process using the first reactant gas, the first processing process using the second source gas, and the second processing process using the second reactant gas. Therefore, the substrate processing method according to a modified embodiment of the present inventive concept may be implemented to form a first thin film using the first source gas and the first reactant gas and a second thin film using the second source gas and the second reactant gas. Therefore, the substrate processing method according to a modified embodiment of the present inventive concept may perform a processing process for manufacturing a device having various characteristics like a device having a multi thin film structure. Also, the substrate processing method according to a modified embodiment of the present inventive concept is implemented to sequentially perform the first processing process using the first source gas, the second processing process using the first reactant gas, the first processing process using the second source gas, and the second processing process using the second reactant gas in a state where a substrate supported by the supporting unit 3 stops. Accordingly, the substrate processing method according to a modified embodiment of the present inventive concept may adjust an incubation time needed for thin film growth in each of the first processing process and the second processing process.

When the second processing process using the second reactant gas is completed, the substrate processing method according to a modified embodiment of the present inventive concept may move the substrate to the first processing region 110. When the second processing process using the second reactant gas is completed, such a step may be performed by rotating the supporting unit 3 to move the substrate S from the second processing region 120 to the first processing region 110. When the substrate S is disposed in the first processing region 110, each step may be again performed from a step of performing the first processing process using the first source gas. Accordingly, by repeatedly performing a process described above, the substrate processing method according to a modified embodiment of the present inventive concept may perform a processing process on the substrate S.

The present inventive concept described above are not limited to the above-described embodiments and the accompanying drawings and those skilled in the art will clearly appreciate that various modifications, deformations, and substitutions are possible without departing from the scope and spirit of the invention.

1. A method for processing a substrate, which performs a processing process on a substrate in a processing space divided into a first processing region and a second processing region, the method comprising:
a step of performing a first processing process on the substrate in the first processing region when the substrate supported by a supporting unit is disposed in the first processing region;
a step of rotating the supporting unit to move the substrate to the second processing region, when the first processing process is completed; and
a step of performing a second processing process on the substrate in the second processing region when the substrate supported by the supporting unit is disposed in the second processing region,
wherein the step of performing the first processing process comprises:
a step of injecting a first source gas into the first processing region; and
a step of injecting a second source gas into the first processing region.

2. The method of claim 1, wherein the step of performing the first processing process comprises a step of injecting a purge gas into the first processing region.

3. The method of claim 1, wherein the step of performing the first processing process comprises a step of injecting a third source gas into the first processing region.

4. The method of claim 1, wherein the step of injecting the second source gas into the first processing region injects the second source gas which differs from the first source gas.

5. The method of claim 1, wherein the step of injecting the second source gas into the first processing region injects the second source gas which is the same as the first source gas.

6. The method of claim 1, wherein
the step of injecting the first source gas into the first processing region injects the first source gas for a first source injection time, and
the step of injecting the second source gas into the first processing region injects the second source gas for a second source injection time which differs from the first source injection time.

7. The method of claim 1, wherein
the step of injecting the first source gas into the first processing region injects the first source gas for a first source injection time, and
the step of injecting the second source gas into the first processing region injects the second source gas for a second source injection time which is the same as the first source injection time.

8. The method of claim 1, wherein the step of performing the second processing process comprises a step of injecting a first reactant gas into the second processing region.

9. A method for processing a substrate, which performs a processing process on a substrate in a processing space divided into a first processing region and a second processing region, the method comprising:
a step of performing a first processing process on the substrate in the first processing region when the substrate supported by a supporting unit is disposed in the first processing region;
a step of rotating the supporting unit to move the substrate to the second processing region, when the first processing process is completed; and
a step of performing a second processing process on the substrate in the second processing region when the substrate supported by the supporting unit is disposed in the second processing region,
wherein the step of performing the second processing process comprises:
a step of injecting a first reactant gas into the second processing region; and
a step of injecting a second reactant gas into the second processing region.

10. The method of claim 9, wherein the step of performing the second processing process comprises a step of injecting a purge gas into the second processing region.

11. The method of claim 9, wherein
the step of injecting the second reactant gas into the second processing region injects the second reactant gas which differs from the first reactant gas, and
the step of performing the second processing process comprises a step of injecting a third reactant gas, which differs from each of the first reactant gas and the second reactant gas, into the second processing region.

12. The method of claim 9, wherein the step of performing the second processing process comprises a step of generating plasma in the second processing region.

13. The method of claim 9, wherein the step of performing the first processing process comprises a step of injecting a first source gas into the first processing region.

14. A method for processing a substrate, which performs a processing process on a substrate in a processing space divided into a first processing region and a second processing region, the method comprising:
a step of performing a first processing process on the substrate in the first processing region when the substrate supported by a supporting unit is disposed in the first processing region;
a step of rotating the supporting unit to move the substrate to the second processing region, when the first processing process is completed; and
a step of performing a second processing process on the substrate in the second processing region when the substrate supported by the supporting unit is disposed in the second processing region, wherein
the step of performing the first processing process injects a mixed gas, where two or more kinds of source gases are mixed, into the first processing region, and
the step of performing the second processing process injects a mixed gas, where two or more kinds of reactant gases are mixed, into the second processing region.

15. (canceled)

16. (canceled)

17. The method of claim 1, wherein the step of performing the second processing process comprises:
a step of injecting a first reactant gas into the second processing region; and
a step of generating plasma in the second processing region.

18. The method of claim 1, wherein
the step of injecting the first source gas into the first processing region injects the first source gas for a first source injection time, and
the step of injecting the second source gas into the first processing region injects the second source gas for a second source injection time which differs from the first source injection time, the second source gas which differs from the first source gas.
